(19) United States
(12) Patent Application Publication
(10) Pub. No.: US 2006/0051596 A1
(43) Pub. Date: Mar. 9, 2006

(54) Nickel silicides formed by low-temperature annealing of compositionally modulated multilayers

(76) Inventors: Jacob M Jensen, Beaverton, OR (US); David Johnson, Eugene, OR (US)

Correspondence Address: KLARQUIST SPARKMAN, LLP, 121 SW SALMON STREET, SUITE 1600, PORTLAND, OR, 97204, US

(21) Appl. No.: 10/529,311

(22) PCT Filed: Sep. 26, 2003
(86) PCT No.: PCT/US03/30472

§ 371 Date: Mar. 25, 2005

Related U.S. Application Data
(60) Provisional application No. 60/414,010, filed on Sep. 26, 2002.

(51) Int. Cl. B32B 17/06; B32B 13/04; B32B 15/04; C03C 27/02

(52) U.S. Cl. 428/426; 428/432; 428/433; 428/469; 428/446; 428/450; 428/688; 428/699; 428/615; 428/621; 428/632; 427/58; 427/248.1; 427/372.2; 427/402

(57) ABSTRACT

Methods are disclosed for making a compound of nickel and silicon. According to an embodiment, on a surface of a substrate (e.g., silicon), multiple layer pairs are formed in a superposed manner. Each layer pair includes a respective layer of nickel and a respective layer of silicon each being 3 nm or less in thickness. The layers of nickel and silicon in the multiple layer pairs are formed in alternating order, thereby forming a multilayer structure, wherein the layers of nickel and silicon in the multilayer structure are formed at respective thicknesses corresponding to desired mole fractions of nickel and silicon in the multilayer structure. The multilayer structure is annealed at a temperature of 200° C. or less to form an amorphous alloy of nickel and silicon in the multilayer structure, wherein the alloy has the desired mole fractions of nickel and silicon. The amorphous alloy is allowed to nucleate and form a corresponding crystalline alloy having the desired mole fractions of nickel and silicon.

### CROSS REFERENCE TO RELATED APPLICATION

This application claims the benefit of the earlier priority date of U.S. provisional patent application No. 60/414,010, filed on Sep. 26, 2002, which is incorporated herein by reference.

### FIELD

This disclosure concerns solid-state structures of silicon and nickel and methods for making and using these structures.

### BACKGROUND

A great need exists for new materials for use in the fabrication of microelectronic devices such as integrated circuits, displays, and the like. Many of the materials currently being used for these applications have limitations that can diminish their effectiveness in devices of which the dimensions of active circuit elements are at or near the currently achievable critical dimensions. Hence, there is a persistent need for new materials that can be used under increasingly demanding process conditions. For example, there is a need for new materials that can be used for forming electrical interconnections under conditions in which modern microelectronic devices will have to be manufactured. In other words, new materials are required that exhibit satisfactory mechanical and electrical properties when formed or otherwise used under conditions of ever-increasing miniaturization of active circuit elements and their interconnections.

A key impetus behind the development of new materials is the need to decrease contact resistivity between active elements and adjacent metal layers. For example, the sources, gates, and drains of MOS transistors within a microelectronic device must be connected to metal layers that define conductive interconnections allowing the transistors to communicate with each other and with external devices. Aluminum and copper currently are the most common materials used for forming these metal interconnecting layers. Silicon, on the other hand, is the most common material used for forming active circuit elements (e.g., sources, gates, and drains of MOS transistors). If aluminum is deposited directly onto a source, gate, or drain of a MOS transistor, the aluminum can diffuse into the silicon and destroy the transistor. To avoid this problem, a separate metal layer usually is formed between the silicon of the active element and the aluminum of the metal-interconnect layer as a diffusion barrier. Unfortunately, the currently most effective barrier metals (tungsten and molybdenum) have high respective contact resistances to silicon. High contact resistance between the barrier layer and the underlying silicon adversely affects the performance of the microelectronic device and leads to destructive heat generation during operation of the device.

Today, silicides (alloys of silicon and at least one metal) often are formed below the barrier layer to improve conductivity between the barrier layer and the underlying silicon. Silicides are advantageous for this purpose because they exhibit low contact resistance to both silicon and the commonly used barrier materials. The silicide typically is formed by depositing a thin metal film on an area of exposed (bare) silicon associated with a respective active circuit element. During or after deposition of the metal, a reaction between the metal and the silicon occurs by establishing annealing conditions. Titanium and cobalt are currently the most commonly used metals for forming silicides in silicon-based microelectronic devices. Unfortunately, both these elements have serious limitations. Hence, new silicide materials are needed for current and next-generation applications in microelectronic-device fabrication.

One of the desired properties for a silicide is low resistivity. For example, the C54 phase of TiSi₂ has an attractively low resistivity of 13-16 μΩ·cm, compared to CoSi₂ and NiSi each having a resistivity in the range of 14-20 μΩ·cm. Even though TiSi₂ exhibits lower resistivity than CoSi₂ or NiSi, TiSi₂ is difficult to form at the smaller dimensions utilized in modern microelectronic devices. For example, at line widths of less than 0.20 μm, nucleation of the C54 phase of TiSi₂ does not occur in conventional methods. Instead, TiSi₂ crystallizes as a C49 phase, which has a relatively high resistivity of 60-70 μΩ·cm. Another problem with forming TiSi₂ is agglomeration. At high annealing temperatures, TiSi₂ forms separate agglomerates that substantially increase the resistivity between the barrier metal and the underlying silicon. CoSi₂ does not exhibit agglomeration or these nucleation problems at narrow line widths, but this compound also has undesirable properties. Particularly, CoSi₂ can diffuse into the underlying active area, causing a rough silicon-silicide interface and current leakage across the junction. Formation of CoSi₂ also consumes a relatively large amount of the underlying silicon, which can cause problems in devices having shallow junction depths.

Nickel suicides have been considered as potential next-generation contact materials for silicon microelectronic devices, but specific nickel-silicide compounds are excessively difficult or impossible to form using conventional methods. As with other suicides, multiple phases of nickel silicide tend to form by a nickel-silicon solid-state reaction. In a conventional method for forming nickel silicide, the first nucleated phase formed in the metal-silicon solid-state reaction usually is not the most desirable silicide. For example, in a conventional method, a high-resistivity dinickel silicide phase (Ni₂Si) usually forms first, whereas nickel monosilicide (NiSi) is usually the desired phase.

In one conventional method for forming phase-pure silicide contacts for microelectronic applications, alternating annealing and etching steps are performed. For example, a nickel layer is deposited on silicon, followed by annealing to form crystalline Ni₂Si at the nickel-silicon interface. Excess nickel is etched away and the remaining structure is re-annealed to change the silicide phase to NiSi. The annealing temperatures required for these steps are often the highest temperatures used in the microelectronic-device-fabrication process. With increasing miniaturization of microelectronic devices, these higher temperatures no longer can be tolerated, necessitating the need for lower-temperature steps capable of forming the desired silicide compound.

A second conventional method for forming phase-pure silicide contacts for microelectronic applications involves the deposition of a thin, interfacial layer between the silicon and the overlying metal layer, followed by annealing. The interfacial layer helps modulate the first nucleated phase by limiting the amount of metal available for reaction at the interface. Exemplary conventional interfacial layers that have been investigated comprise titanium or a combination of palladium and platinum. While such an interfacial layer can facilitate the formation of NiSi at a contact of Ni with Si, the interfacial layer also tends to form one or more other, unwanted, phases that compromise the resistivity of the contact. This problem becomes more pronounced with decreasing dimensions of the contact.

### SUMMARY

The foregoing and other shortcomings of conventional methods are satisfied by compositions and methods as disclosed herein. According to a first aspect, compositions of matter are disclosed. An embodiment of such a composition comprises a substrate and a multilayer structure formed on the surface of the substrate. The multilayer structure comprises multiple superposed layer pairs, wherein each layer pair consists of a first layer of silicon and a second layer of nickel and having a layer-pair thickness of 3.0 nm or less.

The substrate can be any of various materials such as a semiconductor material, a metal, a glass material, a crystalline material, and a ceramic material. For example, the surface of the substrate can be a surface of a silicon layer applied to the substrate. Alternatively, the substrate can be silicon in any of various forms, including but not limited to doped silicon.

The composition desirably exhibits an electrical conductivity, from the multilayer structure to the substrate, of less than 13 μΩ·cm.

The multilayer structure desirably comprises two to ten layer pairs and desirably comprises equal molar percentages of nickel and silicon. Alternatively, the multilayer structure can comprise more than 50 mole-percent of nickel. The multilayer structure can be amorphous NiSi, with an optional capping layer (desirably of nickel), or crystalline NiSi, with an optional capping layer (again, desirably of nickel).

According to another aspect, methods are provided for making a compound of nickel and silicon. In an embodiment of the method multiple layer pairs are formed on the surface of a substrate in a superposed manner. Each layer pair comprises a respective layer of nickel and a respective layer of silicon each being 3 nm or less in thickness. The layers of nickel and silicon in the multiple layer pairs are formed in alternating order, thereby forming a multilayer structure, wherein the layers of nickel and silicon in the multilayer structure are formed at respective thicknesses corresponding to desired mole fractions of nickel and silicon in the multilayer structure. In another step the multilayer structure is annealed at an annealing temperature of 200° C. or less to form an amorphous alloy of nickel and silicon in the multilayer structure, wherein the alloy has the desired mole fractions of nickel and silicon. In yet another step the amorphous alloy is allowed to nucleate and form a corresponding crystalline alloy having the desired mole fractions of nickel and silicon. The substrate can be any of various materials as summarized above. If necessary or desired, the surface of the substrate (e.g., a silicon surface) is cleaned before forming the multilayer structure on the silicon surface.

The step of allowing the amorphous alloy to nucleate desirably is performed by annealing the amorphous alloy at an annealing temperature of 350° C. or less. Desirably, at onset of annealing, the annealing temperature is ramped up to the annealing temperature.

As noted above, the number of layer pairs is two to ten, but the number can be as great as necessary or desired. The layers of silicon and nickel desirably are formed at respective thicknesses sufficient to form the multilayer structure having substantial equal mole percentages of nickel and silicon. Alternatively, the layers of silicon and nickel are formed at respective thicknesses sufficient to form the multilayer structure having more than 50 mole-percent of nickel. Each of the nickel layers and each of the silicon layers can be formed by a suitable technique such as electron beam evaporation.

The method further can comprise the step of forming a capping layer superposedly on the multilayer structure. The capping layer can be, for example, a layer of nickel, typically formed at a thickness greater than a nickel-layer thickness in the multilayer structure.

According to another aspect, methods are provided (in the context of a microelectronic-device fabrication method) for providing a low-resistivity contact to a silicon-containing active-circuit element (e.g., to a metal conductor). In an embodiment of such a method, multiple layer pairs are formed in a superposed manner on a region of the surface of the active-circuit element. Each layer pair comprises a respective layer of nickel and a respective layer of silicon each being 3 nm or less in thickness. The layers of nickel and silicon in the multiple layer pairs are formed in alternating order, thereby forming a multilayer structure, wherein the layers of nickel and silicon in the multilayer structure are formed at respective thicknesses corresponding to desired mole fractions of nickel and silicon in the multilayer structure. In another step the multilayer structure is annealed at an annealing temperature of 200° C. or less to form an amorphous alloy of nickel and silicon in the multilayer structure, wherein the alloy has the desired mole fractions of nickel and silicon. In yet another step the amorphous alloy is allowed to nucleate and form a corresponding crystalline alloy having the desired mole fractions of nickel and silicon.

The method can comprise the step, after forming the crystalline alloy, of connecting a metal conductor to the crystalline alloy. This step can be performed on a capping layer applied to the multilayer structure. The step of allowing the amorphous alloy to nucleate desirably is performed by annealing the amorphous alloy at an annealing temperature of 350° C. or less. As noted above, the annealing temperature desirably is reached by ramping.

The method further can comprise the step of cleaning the surface of the active-circuit element before forming the multilayer structure on the silicon surface.

The foregoing and additional features and advantages will be more readily apparent from the following detailed description, which proceeds with reference to the accompanying drawings.

### BRIEF DESCRIPTION OF THE DRAWINGS

FIG. 1 is an elevational view of a first representative embodiment of a nickel-silicon multilayer structure.

FIG. 2 is an elevational view of a second representative embodiment of a nickel-silicon multilayer structure.

FIG. 3 is an elevational view of an exemplary intermediate structure formed during annealing of the structure of either FIG. 1 or FIG. 2.

FIG. 4 is an elevational view of an exemplary product formed upon completing annealing of the structure of either FIG. 1 or FIG. 2.

FIG. 5 is a plot of exemplary grazing-angle diffraction data obtained in the Example from as-deposited samples.

FIG. 6 is a plot of exemplary grazing-incidence diffraction data as a function of annealing temperature for sample J052 in the Example.

FIG. 7 is a plot of exemplary grazing-incidence diffraction data as a function of annealing temperature for sample J053 in the Example.

FIG. 8 is a plot of exemplary grazing-incidence diffraction data as a function of annealing temperature for sample J054 in the Example.

### DETAILED DESCRIPTION

The present disclosure encompasses, inter alia, methods for preparing binary and higher phases of nickel (Ni) and silicon (Si) using compositionally modulated multilayers as reactive precursors. The disclosure also encompasses the Ni—Si multilayer structures. The term “multilayer” herein denotes the result of a method in which layers of Si and Ni are alternatingly deposited on a substrate in a sequential manner, yielding multiple superposed layer pairs. It will be understood that the actual structure of the resulting composition does not necessarily exhibit individually defined layers. Hence the term “multilayer” reflects the sequential deposition procedure used for forming the structure rather than the actual structure of the resulting composition. In some cases the actual structure of the resulting composition will exhibit substantial stratification; in other cases stratification will be less pronounced; and in yet other cases the structure formed on the substrate will be amorphous and uniform.

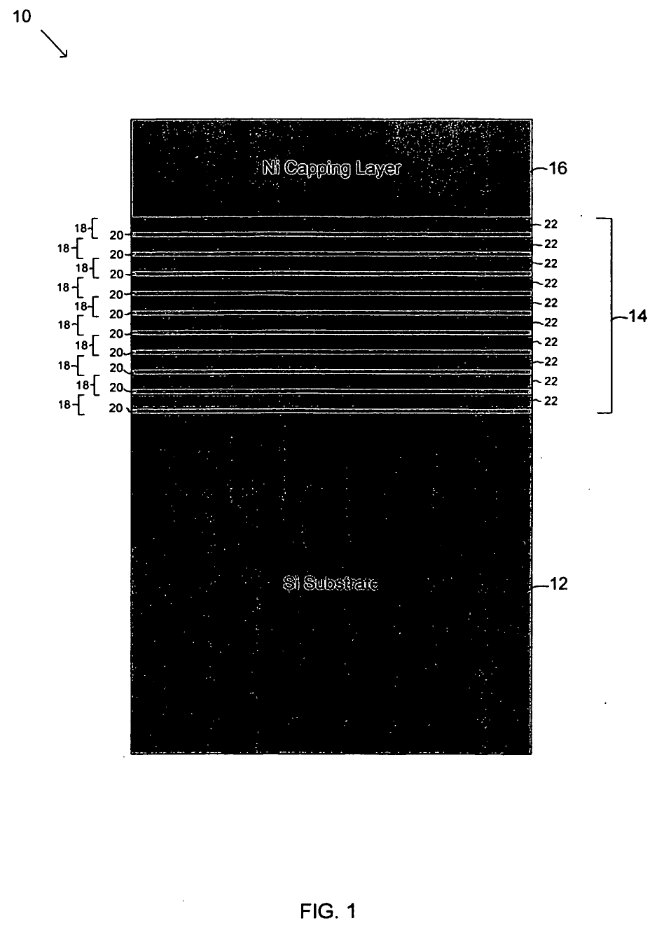

A first representative embodiment of a multilayer structure 10 is shown in FIG. 1. The depicted multilayer structure 10 comprises a silicon substrate 12, an overlying multilayer structure 14, and a Ni capping layer 16 overlying the multilayer structure 14. The multilayer structure 14 comprises multiple layer pairs 18. Each layer pair 18 comprises a respective layer of nickel 20 and a respective layer of silicon 22. Each nickel layer 20 and each silicon layer 22 desirably is of the respective element in substantially pure form. In this embodiment, the nickel layers 20 and the silicon layers 22 contain approximately equimolar amounts of the respective element, but are not equal in thickness. The difference in the thickness of nickel layers 20 and silicon layers 22 reflects the difference in molar volume between the two elements. The capping layer 16 desirably is thicker than any one of the nickel layers 20.

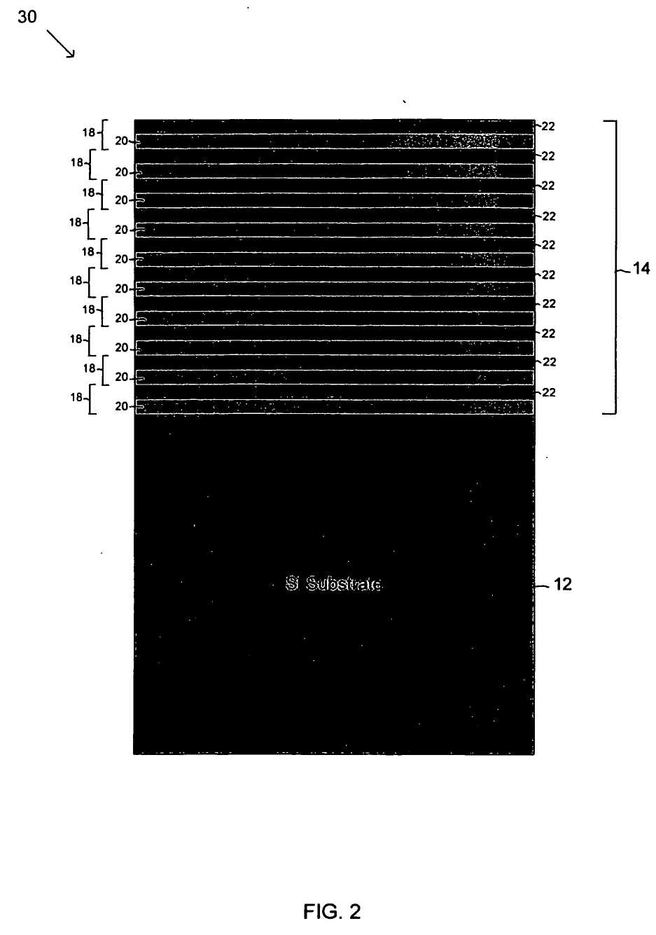

A second representative embodiment of a multilayer structure 30 is shown in FIG. 2, in which features that are similar to corresponding features in FIG. 1 have the same respective reference numerals. The multilayer structure 30 is similar to the multilayer structure 10 in FIG. 1, but includes thicker nickel layers 20 and no capping layer 16. The total nickel content of the multilayer structure 14, in this embodiment, is similar to the total nickel content of the combination of the multilayer structure 14 and the nickel capping layer 16 in the embodiment of FIG. 1.

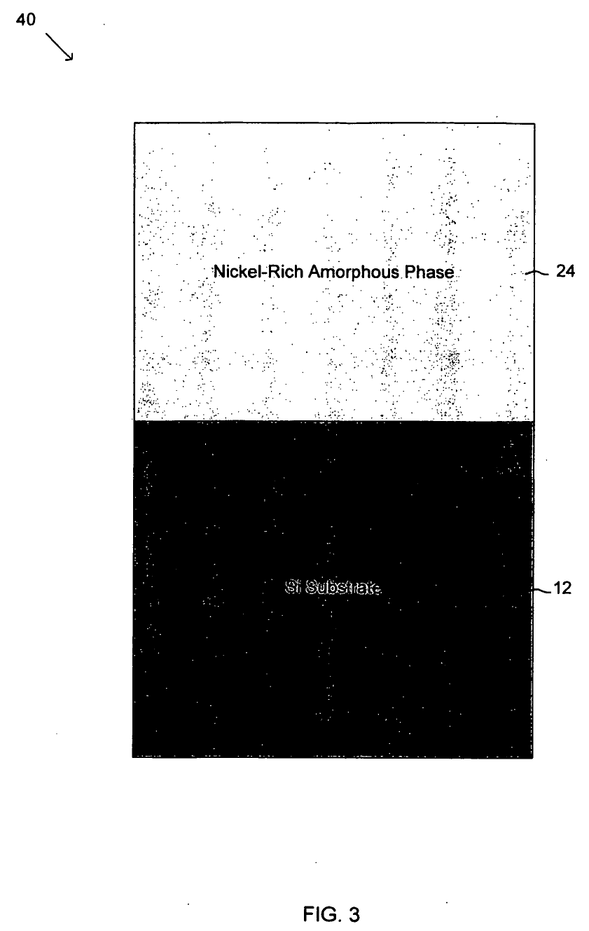

A third representative embodiment of a multilayer structure 40 is shown in FIG. 3, which depicts a possible intermediate structure formed during annealing of the multilayer structure 10 in FIG. 1 or the multilayer structure 30 in FIG. 2. The depicted multilayer 40 comprises a silicon substrate 12 and an overlying nickel-rich amorphous region 24.

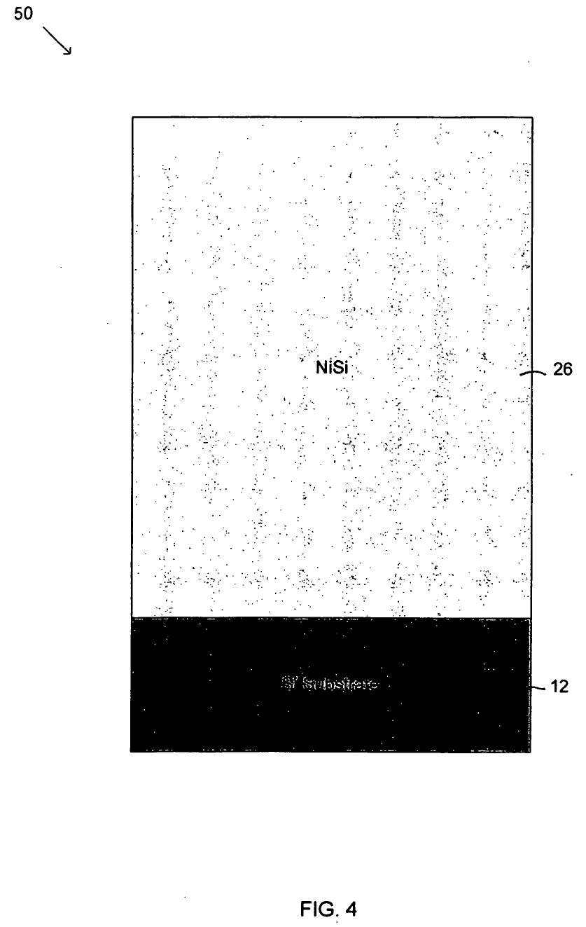

A fourth representative embodiment of a multilayer structure 50 is shown in FIG. 4, which depicts a final product created by annealing the multilayer structure 10 in FIG. 1 or the multilayer structure 30 in FIG. 2. The post-anneal structure 50 comprises a silicon substrate 12 and an overlying layer 26 of NiSi.

A representative embodiment of a method for making a compositionally modulated multilayer structure is performed on a suitable substrate such as silicon.

Alternatively, the substrate can be any other suitable solid material such as another semiconductor material, a glassy material, a crystalline material, or a ceramic material. The substrate may or may not have an overlying layer of dielectric, doped semiconductor, or the like, according to prevailing requirements. In many microelectronic-device-fabrication methods that include the subject method for making a compositionally modulated multilayer structure, the silicide will be formed on exposed silicon, e.g., over the junctions and gates of transistors, following the formation of the sources, drains, gates, and oxide spacers (as required) of the transistors. However, it will be understood that the multilayer structures can be formed on any of various surfaces of silicon or other suitable substrate. The description below is in the context, by way of example, of using silicon as the substrate.

The method typically begins by preparing the substrate 12, which in this instance is silicon or another material on which a silicon layer has been formed. This step of preparing the substrate can include, for example, stripping native oxide from the silicon surface using a standard wet-clean process. Preparation of the surface of the substrate 12 also or alternatively can include subjecting the surface to a cleaning process suitable for removing particles from the surface.

In a next step of the method, the compositionally modulated multilayer structure 14 is formed. This step can be accomplished by any of various multisource-evaporation processes, the most desirable being electron-beam evaporation, in which the substrate 12 is first placed into a multisource-deposition chamber. The chamber includes respective electron guns that transfer material from first and second elemental sources (i.e., Ni and Si sources) to the substrate 12. Deposition rates of the elements onto the substrate 12 can be monitored in situ using a quartz-crystal microbalance or monitored ex situ by x-ray reflectivity. The desired modulation of respective concentrations of Ni and Si in the multilayer structure 14 can be achieved by alternating the deposition of the Ni and Si. After formation of the compositionally modulated multilayer structure 14, a capping layer 16 (e.g., a thick layer of Ni) can be deposited in the same manner, using a Ni source in the chamber.

The compositionally modulated multilayer structure 14 is subjected to a first annealing step to convert the region into phase-pure NiSi. Any of various annealing conditions will achieve the desired conversion. For example, annealing at 350° C. for one hour with a staged ramp-up in temperature is effective for converting the multilayers in the region 14 into phase-pure NiSi. This first annealing step can be carried out in a standard furnace.

It is theorized that, during this first annealing step but prior to crystallization of NiSi in the region 14, the individual Ni layers 20 and Si layer 22 interdiffuse with each other and with the capping layer 16 to form an amorphous phase 24. Ni diffuses rapidly through the amorphous phase 24, whereas the diffusion rate of amorphous NiSi into silicon is slower. Thus, at a moderate annealing temperature, Ni is expected to diffuse readily in the capping layer 16 and in the layers 20, 22 of the multilayer structure 14 without appreciable diffusion of Ni at the interface between the multilayer structure 14 and the substrate 12. After concluding the first annealing step, a second annealing step is performed at a higher annealing temperature than the first annealing step. The second annealing step causes nucleation of pure NiSi (as a first nucleated phase) in the amorphous phase 24, beginning at the interface between the amorphous phase 24 and the silicon substrate 12.

In an alternative scenario, the individual layers 20, 22 in the multilayer structure 14 interdiffuse with each other, but not with the capping layer 16, to form an amorphous phase 24 containing approximately equivalent concentrations of nickel and silicon. In this scenario, nucleation that begins within the amorphous phase 24 results in the formation of a first nucleated phase of NiSi.

The stoichiometry of the first nucleated phase is dictated by the elemental composition adjacent the nucleation site(s). If a multilayer structure 14, comprising roughly equivalent molar concentrations of silicon and nickel (as illustrated in FIG. 1), interdiffuses with a nickel capping layer 16, the resulting amorphous phase 24 is relatively nickel-rich. A nickel-rich amorphous phase 24 also can be created by annealing a multilayer structure 14 in which the molar proportion of Ni is greater than of Si, as illustrated in FIG. 2 in which the Ni layers 20 are thicker (relative to the Si layers 22) than in the embodiment of FIG. 1. Thus, the stoichiometry immediately surrounding the interface between the nickel-rich amorphous phase 24 and the substantially pure silicon of the substrate 12 will dictate preferential formation of NiSi at the interface so long as crystallization begins at the interface.

Alternatively, if a multilayer structure 14, comprising roughly equivalent concentrations of silicon and nickel, interdiffuses with itself but not with the nickel capping layer 16, NiSi formation still will be achieved so long as nucleation occurs at “embryonic” sites within the amorphous phase 24 rather than at the interface between the substrate 12 and the amorphous phase 24.

Using multilayer structures 14 as reactive precursors provides several advantages for preparing NiSi materials in microelectronic devices. First, the subject methods that result in formation of such regions can be performed using equipment that is similar to equipment already used (for other purposes) in microelectronic-device-fabrication facilities. Second, the subject methods suppress formation of unwanted phases because the desired phase forms directly from the amorphous intermediate.

Nucleation of a particular desired phase can be achieved by adjusting the composition of the multilayer structure 14. The composition of the multilayer structure 14 can be controlled simply by controlling the respective deposition times for each elemental layer 20, 22. The locations of nucleation sites in the amorphous phase 24 and the stoichiometry of the amorphous phase 24 created by interdiffusion of the layers 20, 22 overlying the substrate 12 are key factors in determining the stoichiometry of the first nucleated phase. To cause the formation of a desired crystalline phase, the composition of the layers 20, 22 is adjusted to cause the formation of the desired amorphous phase either immediately upon deposition of the layers 20, 22 or during the first annealing step. Depending on whether nucleation is expected to occur at the interface between the substrate 12 and the amorphous phase 24 or whether nucleation is expected to occur at embryonic sites within the amorphous phase 24, the desired composition of the amorphous phase either will be nickel-rich or will comprise approximately equal concentrations of Ni and Si.

To illustrate, in the Ni—Si system illustrated in FIG. 1, the Ni:Si stoichiometry of the multilayer structure 14 is approximately 1:1. If annealing is performed to cause crystalline-phase nucleation before significant diffusion of Ni from the capping layer 16 into the multilayer structure 14, the nucleations will occur at embryonic sites within the amorphous phase formed from the multilayer structure 14, and the first crystalline phase will be NiSi. Whether nucleation will occur within the amorphous phase depends upon the thickness of the layer pairs 16. During annealing, an amorphous phase begins to form at each Ni—Si interface. If the thickness of any of the layer pairs 16 is excessive, nucleation will occur at the interface between the growing amorphous phase and the adjacent thicker layer pair 16. For example, if the material surrounding the nucleation sites in this scenario is mostly Ni (e.g., because nucleation occurs at interfaces between amorphous phases and Ni layers), then the prevailing stoichiometry dictates formation of an undesirably nickel-rich silicide. If, however, the thickness of each layer pair 16 is below a particular threshold, then each growing unit of amorphous phase formed during annealing will come into contact with adjacently growing units of amorphous phase before onset of crystallization. Thus, a unified amorphous phase is formed that extends beyond the thickness at which crystallization otherwise would occur. Such an amorphous phase has no interface at which nucleation can occur. Hence, nucleation will occur only at embryonic sites within the amorphous phase in which the stoichiometry of the amorphous phase dictates the stoichiometry of the crystalline phase formed at the nucleation sites. For example, a layer-pair thickness of 2.5 nm or less effectively favors nucleation within a Ni—Si amorphous phase.

Alternatively, the annealing steps can be controlled to allow diffusion of the multilayer structure 14 with the nickel capping layer 16 before onset of crystallization. The first annealing step forms a nickel-rich amorphous phase 24. A subsequent ramp-up in temperature initiates nucleations at the interface between the amorphous phase 24 and the silicon of the substrate 12. The stoichiometry surrounding the nucleation sites favors the formation of NiSi.

An advantage of using a multilayered structure of reactant layers is that the constituent layers allow the formation of a desired crystalline phase at a lower temperature than conventionally. In this regard, there are fundamental differences between the present multilayer-synthetic methods and conventional solid-state reactions. In conventional solid-state reactions, complete mixing of the reactants is achievable only at high temperatures. Crystalline-phase formation at the interface between two reactants occurs prior to mixing of the reactants, which favors the formation of multiple crystalline “intermediate” phases en route to the final product. These intermediate phases typically have no relationship, crystallographic or otherwise, to the desired final product. In contrast, using methods as described above, the respective layers and layer pairs in the multilayer structure are sufficiently thin such that complete intermixture of reactant layers is achieved at moderate temperatures, which produces a desired substantially homogeneous amorphous phase prior to onset of nucleation of any crystalline phases. The amorphous phase serves as a reactive intermediate that is a direct precursor to formation of a corresponding crystalline phase. By varying the composition of the multilayer structure (i.e., by appropriate control of layer thicknesses), the composition of the amorphous precursor is controlled, yielding corresponding control of the particular final crystalline product that is formed from the amorphous precursor.

The methods described above are especially useful in the manufacture of microelectronic devices such as integrated circuits, displays, and the like. A particularly advantageous application of the subject methods is in the fabrication of conductive contacts for use in making electrical connections between, for example, active circuit elements and metal conductors in integrated circuits. In such fabrication methods, the loci on active circuit elements at which such electrical connections are to be made typically are defined microlithographically. Since the methods disclosed herein are performed at relatively low temperatures, they can be conducted on patterned semiconductor wafers in many instances without destroying masks and the like that define the loci.

The following example is provided to illustrate certain operational details of a representative embodiment. It will be understood that this example is not limiting in any way and that other embodiments are not limited to the particular details described in this example.

Specifically, in this example a composition comprising substantially pure NiSi was formed on a silicon substrate. The substrate was formed from 100-mm diameter n-type Si(100) wafers (resistivity>6 Ω/cm). The wafers were broken into pieces 1 cm×1 cm. The native oxide was stripped off each piece using a conventional cleaning procedure. Within one hour of stripping the oxide, the silicon pieces were mounted onto scrap 200-mm Si wafers using double-sided Scotch® tape and loaded into an evaporative physical vapor deposition (PVD) chamber (Thermionics, Inc.). Background pressure in the chamber was ˜10⁻⁷ Torr. Ni and Si were deposited using respective electron guns and respective sources at a nominal deposition rate of 0.15 nm/s, as determined using a quartz-crystal monitor. Real deposition rates of 0.04 nm/s for both Ni and Si were confirmed by ex situ x-ray reflectivity.

Three samples were prepared. In each sample, several repeating units (layer pairs) of equimolar Ni and Si layers were deposited at a thickness (per layer pair) of approximately 20 nm. This was followed by depositing a capping layer of nickel at a thickness of approximately 30 nm. Specific deposition details are listed in Table 1, below:

TABLE 1

| | Ni dep (s) | | Si dep (s) | | | | |
|---|---|---|---|---|---|---|---|
| | Target | | Target | | | | |
| | Thickness | | Thickness | | | Ni Cap (s) | |
| | (nm) | | (nm) | | | Target Thickness (nm) | |
| Sample | Thickness determined | | | | Repeat | Thickness determined | |
| ID | by X-Ray Reflectivity | | | | Units | by X-Ray Reflectivity | |
| J052 | 18.8 | s | 37.7 | s | 2 | 667 | s |
| X_{Ni}˜0.95 | 0.72 | nm | 1.45 | nm | | 25.7 | nm |
| | 1.69 nm | | | | | 28.7 | nm |
| J053 | 18.8 | s | 37.7 | s | 5 | 520.8 | s |
| X_{Ni}˜0.86 | 0.72 | nm | 1.45 | nm | | 20.1 | nm |
| | 1.90 nm | | | | | 21.0 | nm |
| J054 | 18.8 | s | 37.7 | s | 10 | 260.4 | s |
| X_{Ni}˜0.70 | 0.72 | nm | 1.45 | nm | | 10.0 | nm |

| | | |
|---|---|---|
| 2.07 nm | 7.67 | nm |

In the foregoing Table multilayer depositions are in units of seconds (s) of deposition time for each constituent element. The term “repeat units” is synonymous with “layer pairs.” The “nickel cap” is the capping layer of nickel, the formation of which is expressed in terms of seconds of deposition time. The variable “X_{Ni}” is the approximate mole fraction of nickel in the entire overlayer (i.e., in the multilayer structure plus in the nickel cap).

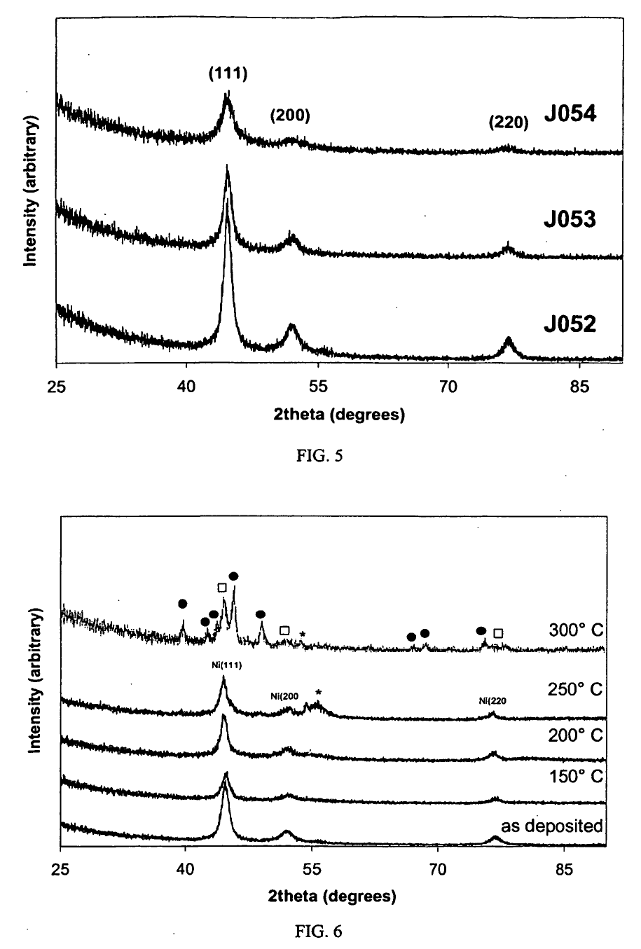

Grazing-angle diffraction data of the as-deposited samples are shown in FIG. 5, which reveals that polycrystalline Ni was present in all three samples. The intensity of the polycrystalline Ni peaks corresponds qualitatively to the thickness of the Ni capping layer. Higher-intensity peaks correspond to thicker caps. Other than peaks corresponding to scattering from the substrate and peaks arising from the capping layer, no other peaks were observed, indicating that the multilayer structure was amorphous upon deposition.

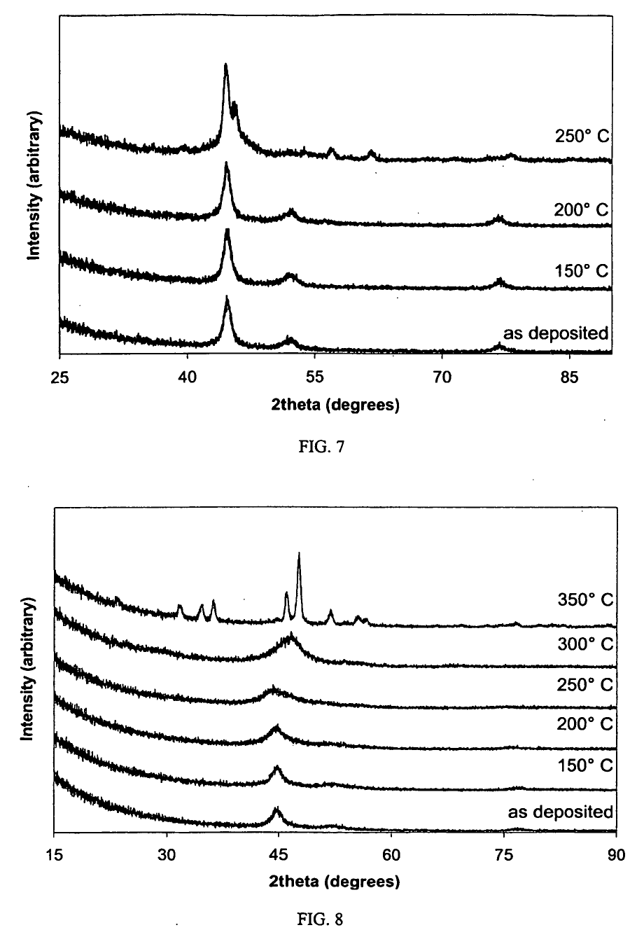

The samples were annealed in a nitrogen atmosphere for one hour at successively higher temperatures. After each annealing step, x-ray reflectivity and grazing-angle diffraction were used to monitor the course of the reaction. Annealing was continued until crystalline-phase nucleation was observed in the grazing-angle-diffraction data. Annealing results are shown in FIG. 6 for sample J052, in FIG. 7 for sample J053, and in FIG. 8 for sample J054.

In sample J052, as deposited, a significant amount of crystalline Ni was observed (FIG. 6). The intensity of the Ni peaks on the reflectivity curve decreased upon annealing. This resulted from the amorphous silicide consuming the available Ni. At 300° C. the diffraction pattern showed a mixture of orthorhombic Ni₂Si (marked “•” in FIG. 6) and the remaining crystalline Ni (marked “□” in FIG. 6). The peak marked “*” in FIG. 6 represents the substrate. The phase evolution observed in sample J052 was similar to that observed in a traditional Ni—Si diffusion couple.

In sample J053, polycrystalline Ni again was the predominant phase as deposited (FIG. 7). At 250° C. nucleation was observed. At 300° C., a mixture of multiple phases was observed, including the remains of the initial Ni layer. Among the phases formed was orthorhombic NiSi.

In sample J054, the Ni was thinner (˜10 nm); thus, the polycrystalline Ni phase was not as pronounced as in the as-deposited sample (FIG. 8). Below 200° C. the diffraction was largely unchanged, with the only apparent peaks belonging to polycrystalline Ni. Upon annealing to 200° C. the Ni peaks began to broaden, while higher-order peaks disappeared altogether. By 250° C. the peak had broadened significantly, suggesting significant interdiffusion of the Ni and NiSi layers. At 300° C. the peaks increased in intensity and shifted to higher angles, wherein the increase in intensity suggests further homogenization of the amorphous phase. Further annealing to 350° C. resulted in the nucleation of NiSi, with no other detectable phases being present.

Whereas the invention has been described above in connection with multiple representative embodiments, the invention is not limited to those embodiments. On the contrary, the invention encompasses all modifications, alternatives, and equivalents as may be included within the spirit and scope of the invention, as defined by the appended claims.

What is claimed is:

1. A composition of matter, comprising:
a substrate having a surface; and
a multilayer structure formed on the surface of the substrate, the multilayer structure comprising multiple superposed layer pairs, each layer pair consisting of a first layer of silicon and a second layer of nickel and having a layer-pair thickness of 3.0 nm or less.

2. The composition of claim 1, wherein the substrate is selected from the group consisting of semiconductor materials, metals, glass materials, crystalline materials, and ceramic materials.

3. The composition of claim 2, wherein the surface of the substrate is a surface of a silicon layer applied to the substrate.

4. The composition of claim 1, wherein the substrate is silicon.

5. The composition of claim 1, exhibiting an electrical conductivity, from the multilayer structure to the substrate, of less than 13 μΩ·cm.

6. The composition of claim 1, wherein the multilayer structure comprises two to ten layer pairs.

7. The composition of claim 1, wherein the multilayer structure comprises more than 50 mole-percent of nickel.

8. The composition of claim 1, wherein the multilayer structure comprises substantially equal mole percentages of silicon and nickel.

9. The composition of claim 1, further comprising a capping layer superposed on the multilayer structure.

10. The composition of claim 7 wherein the capping layer is a layer of nickel.

11. The composition of claim 1, wherein the multilayer structure is an amorphous phase of silicon and nickel.

12. The composition of claim 11 wherein the multilayer structure is amorphous NiSi.

13. The composition of claim 12 further comprising a metal capping layer superposed on the multilayer structure.

14. The composition of claim 13 wherein the metal is nickel.

15. The composition of claim 1, wherein the multilayer structure is crystalline SiNi.

16. The composition of claim 15, further comprising a nickel capping layer.

17. A method for making a compound of nickel and silicon, comprising:
on a surface of a substrate, forming multiple layer pairs in a superposed manner, each layer pair comprising a respective layer of nickel and a respective layer of silicon each being 3 nm or less in thickness, wherein the layers of nickel and silicon in the multiple layer pairs are formed in alternating order, thereby forming a multilayer structure, wherein the layers of nickel and silicon in the multilayer structure are formed at respective thicknesses corresponding to desired mole fractions of nickel and silicon in the multilayer structure;
annealing the multilayer structure at an annealing temperature of 200° C. or less to form an amorphous alloy of nickel and silicon in the multilayer structure, the alloy having the desired mole fractions of nickel and silicon; and
allowing the amorphous alloy to nucleate and form a corresponding crystalline alloy.

18. The method of claim 17, wherein the crystalline alloy has the desired mole fractions of nickel and silicon

19. The method of claim 17, wherein the step of allowing the amorphous alloy to nucleate is performed by annealing the amorphous alloy at an annealing temperature of 350° C. or less.

20. The method of claim 19, wherein the step of annealing the amorphous alloy comprises, at onset of annealing, ramping up to the annealing temperature of 350° C. or less.

21. The method of claim 17, wherein the step of forming the multiple layer pairs is performed on a substrate selected from the group consisting of semiconductor materials, glass materials, ceramic materials, crystalline materials, and metal materials.

22. The method of claim 17, wherein the step of forming the multiple layer pairs is performed on a substrate having a silicon surface.

23. The method of claim 22, further comprising the step of cleaning the silicon surface before forming the multilayer structure on the silicon surface.

24. The method of claim 22, wherein the substrate is silicon.

25. The method of claim 17, wherein the step of forming the multiple layer pairs comprises forming two to ten layer pairs.

26. The method of claim 17, wherein the layers of silicon and nickel are formed at respective thicknesses sufficient to form the multilayer structure having substantial equal mole percentages of nickel and silicon.

27. The method of claim 17, wherein the layers of silicon and nickel are formed at respective thicknesses sufficient to form the multilayer structure having more than 50 mole-percent of nickel.

28. The method of claim 17, further comprising the step of forming a capping layer superposedly on the multilayer structure.

29. The method of claim 28, wherein the capping layer is a layer of nickel.

30. The method of claim 17, wherein each of the nickel layers and each of the silicon layers is formed by electron beam evaporation.

31. A compound of nickel and silicon formed by the method recited in claim 17.

32. The compound of claim 31, wherein the compound is a crystalline alloy of silicon and nickel.

33. In a microelectronic-device fabrication method, a method for providing a silicon-containing active-circuit element with a low-resistivity contact, the method comprising:
on a region of the surface of the active-circuit element, forming multiple layer pairs in a superposed manner, each layer pair comprising a respective layer of nickel and a respective layer of silicon each being 3 nm or less in thickness, wherein the layers of nickel and silicon in the multiple layer pairs are formed in alternating order, thereby forming a multilayer structure, wherein the layers of nickel and silicon in the multilayer structure are formed at respective thicknesses corresponding to desired mole fractions of nickel and silicon in the multilayer structure;
annealing the multilayer structure at an annealing temperature of 200° C. or less to form an amorphous alloy of nickel and silicon in the multilayer structure, the alloy having the desired mole fractions of nickel and silicon; and
allowing the amorphous alloy to nucleate and form a corresponding crystalline alloy.

34. The method of claim 33, wherein the crystalline alloy has the desired mole fractions of nickel and silicon.

35. The method of claim 33, further comprising the step, after forming the crystalline alloy, of connecting a metal conductor to the crystalline alloy so as to establish a low-resistivity contact between the active-circuit element and the metal conductor.

36. The method of claim 33, further comprising the step of forming a capping layer on the multilayer structure before annealing the multilayer structure.

37. The method of claim 36, wherein the capping layer is a layer of nickel.

38. The method of claim 36, further comprising the step, after forming the crystalline alloy, of connecting a metal conductor to the crystalline alloy so as to establish a low-resistivity contact between the active-circuit element and the metal conductor.

39. The method of claim 33, wherein the step of allowing the amorphous alloy to nucleate is performed by annealing the amorphous alloy at an annealing temperature of 350° C. or less.

40. The method of claim 39, wherein the step of annealing the amorphous alloy comprises, at onset of annealing, ramping up to the annealing temperature of 350° C. or less.

41. The method of claim 33, further comprising the step of cleaning the surface of the active-circuit element before forming the multilayer structure on the silicon surface.

42. The method of claim 33, wherein the step of forming the multiple layer pairs comprises forming two to ten layer pairs.

43. The method of claim 33, wherein the layers of silicon and nickel are formed at respective thicknesses sufficient to form the multilayer structure having substantial equal mole percentages of nickel and silicon.

44. The method of claim 33, wherein the layers of silicon and nickel are formed at respective thicknesses sufficient to form the multilayer structure having more than 50 mole-percent of nickel.

45. The method of claim 33, wherein each of the nickel layers and each of the silicon layers is formed by electron beam evaporation.

46. A microelectronic device, comprising low-resistivity contacts formed as recited in claim 33.
